(19) United States
(12) Patent Application Publication
(10) Pub. No.: US 2015/0034967 A1
(43) Pub. Date: Feb. 5, 2015

(54) SEMICONDUCTOR DEVICE

(71) Applicant: FUJITSU LIMITED, Kawasaki-shi (JP)

(72) Inventor: Tetsuro Ishiguro, Kawasaki (JP)

(73) Assignee: FUJITSU LIMITED, Kawasaki (JP)

(21) Appl. No.: 14/515,712

(22) Filed: Oct. 16, 2014

Related U.S. Application Data
(62) Division of application No. 13/547,349, filed on Jul. 12, 2012.

(30) Foreign Application Priority Data
Sep. 28, 2011 (JP) 2011-213473

(51) Int. Cl. H01L 29/778; H01L 29/20

(52) U.S. Cl. CPC H01L 29/7787; H01L 29/2003
USPC 257/76

(57) ABSTRACT

A semiconductor device including a high resistance layer formed on a substrate, the high resistance layer being formed with a semiconductor material doped with as impurity element that makes the semiconductor material highly resistant; a multilayer intermediate layer formed on the high resistance layer; an electron transit layer formed with a semiconductor material on the multilayer intermediate layer; and an electron supply layer formed with a semiconductor material on the electron transit layer, wherein the multilayer intermediate layer is formed with a multilayer film in which a GaN layer and an AlN layer are alternately laminated.

### CROSS-REFERENCE TO RELATED APPLICATION

This patent application is a Divisional Application of U.S. Ser. No. 13/547,349 filed Jul. 12, 2012 which claims the benefit of priority of Japanese Patent Application No. 2011-213473 filed on Sep. 28, 2011, the entire contents of which are incorporated herein by reference.

### FIELD

The embodiments discussed herein are related to a semiconductor device.

### BACKGROUND

GaN, AlN, InN, which are nitride semiconductors or materials made of mixed crystals thereof, have a wide band gap, and are used as high output electronic devices or short-wavelength light emitting devices. Among these, as high output electronic devices, technologies are developed in relation to Field Effect Transistors (FET), more particularly, High Electron Mobility Transistors (HEMT) (see, for example, Japanese Laid-Open Patent Publication Ho. 2002-3592565). A HEMT using such a nitride semiconductor is used for high output/high efficiency amplifiers and high power switching devices.

A HEMT using such a nitride semiconductor has an aluminum gallium nitride/gallium nitride (AlGaN/GaN) hetero structure formed on a substrate, and uses a GaN layer as an electron transit layer. The substrate is made of, for example, sapphire, silicon carbide (SiC), gallium nitride (GaN), and silicon (Si).

Among nitride semiconductors, GaN has a high saturated electron velocity, a wide band gap, and a high pressure resisting feature, and therefore has good electric properties. Furthermore, GaN has a wurtzite form crystal structure, and therefore has a polarity in a (0001) direction parallel to a c-axis. Furthermore, when a hetero structure of AlGaN/GaN is formed, in the AlGaN layer, a piezo polarization is excited by lattice distortion of both AlGaN and GaN in the AlGaN layer.

Incidentally, it is known that by doping a semiconductor layer of a GaN system with an appropriate amount of Fe, the resistance is increased. This is because near the valence band of GaN, an acceptor level deeper than Fe is formed. Therefore, in a HEMT using a semiconductor material such as GaN, by doping the bottom layer of the electron transit layer with Fe, it is possible to prevent vertical leaks and improve pinch-off properties, thus improving the properties of the HEMT.

FIG. 1 illustrates a HEMT using GaN, having a high resistance layer doped with Fe. Specifically, on a substrate 911, a nucleation layer 912 formed with AlN and a buffer layer 913 formed with AlGaN are formed, and then a high resistance layer 914, an electron transit layer 915, and an electron supply layer 916 are formed by epitaxial growth. The high resistance layer 914 is formed with GaN doped with Fe (Fe-doped GaN), the electron transit layer 915 is formed with GaN, and the electron supply layer 916 is formed with AlGaN. On the electron supply layer 916, a gate electrode 921, a source electrode 922, and a drain electrode 923 are formed. In a HEMT using GaN having this structure, the Fe doped in the high resistance layer 914 segregated on the surface, and is sequentially taken in during the growth of the electron transit layer 915, and therefore the Fe enters the electron transit layer 915. When a large amount of Fe enters the electron transit layer 915, the channel electrons get trapped, causing the density of 2DEG to decrease and the mobility to decrease due to an impurity scattering effect, which deteriorates electric properties.

Accordingly, between the high resistance layer 914 doped with Fe and the electron transit layer 915, an intermediate layer is formed with AlN and AlGaN that are highly effective in taking in Fe. Thus, Fe is prevented from entering the electron transit layer 915 (see, for example, Japanese Laid-Open Patent Publication No. 2010-182872 and Japanese Laid-Open Patent Publication No. 2010-232297).

However, in order to prevent Fe from entering the electron transit layer, the intermediate layer formed with AlN or AlGaN is to have a certain thickness. Furthermore, when the intermediate layer is formed with AlGaN, the composition ratio of Al is preferably high. In Japanese Laid-Open Patent Publication No. 2010-182872, the composition ratio of Al is 0.4 or more, and in Japanese Laid-Open Patent Publication No. 2010-232297, the composition ratio of Al is 0.3 or more.

Incidentally, when a substrate having a high lattice mismatch factor with respect to GaN is used, such as an Si substrate, a buffer layer made of AlN or AlGaN having a lower lattice constant than GaN is formed on the Si substrate, and an electron transit layer such as GaN is formed on the buffer layer. By forming the buffer layer as described above, the semiconductor laminated film such as GaN formed on the Si substrate and the entire substrate are balanced, so that the substrate is prevented from bending and cracks are prevented from being formed in the semiconductor laminated film. The intermediate layer is formed on the buffer layer by crystal growth. When the intermediate layer is made or AlN or AlGaN having a relatively high Al composition ratio, the intermediate layer is formed on a buffer layer having a higher lattice constant than the intermediate layer. Therefore, the lattice intervals of the intermediate layer become wider than a distortion-free state, due to tensile distortion caused by the buffer layer. Thus, it is difficult to attain the desired thickness without causing cracks in the intermediate layer. The lattice constant of AlN is 3.11 Å along the a-axis and 4.98 Å along the c-axis, and the lattice constant of GaN is 3.18 Å along the a-axis and 5.17 Å along the c-axis.

### SUMMARY

According to an aspect of the embodiments, a semiconductor device includes a high resistance layer formed on a substrate, the high resistance layer being formed with a semiconductor material doped with an impurity element that makes the semiconductor material highly resistant; a multilayer intermediate layer formed on the high resistance layer; an electron transit layer formed with a semiconductor material on the multilayer intermediate layer; and an electron supply layer formed with a semiconductor material on the electron transit layer, wherein the multilayer intermediate layer is formed with a multilayer film in which a GaN layer and an AlN layer are alternately laminated.

The object and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 illustrates a semiconductor device having a layer doped with Fe;

FIGS. 2A and 2B illustrate a semiconductor laminated film without AlN and a semiconductor laminated film with AlN;

FIG. 3 indicates analysis results obtained by SIMS in the semiconductor laminated film;

FIGS. 4A and 4B illustrate a semiconductor device according to a first embodiment;

FIG. 5 illustrates a multilayer intermediate layer;

FIG. 6 illustrates Fe that has entered in the semiconductor device according to the first embodiment;

FIGS. 7A and 7B illustrate a semiconductor device according to a second embodiment;

FIG. 8 illustrates a semiconductor device according to a third embodiment;

FIG. 9 illustrates a semiconductor device according to a fourth embodiment;

FIG. 10 illustrates a discretely packaged semiconductor device according to a fifth embodiment;

FIG. 11 is a circuit diagram of a power unit according to the fifth embodiment; and

FIG. 12 illustrates a high-frequency amplifier according to the fifth embodiment.

### DESCRIPTION OF EMBODIMENTS

Preferred embodiments of the present invention will be explained with reference to accompanying drawings. The same elements are denoted by the same reference numerals and overlapping descriptions are omitted.

### First Embodiment

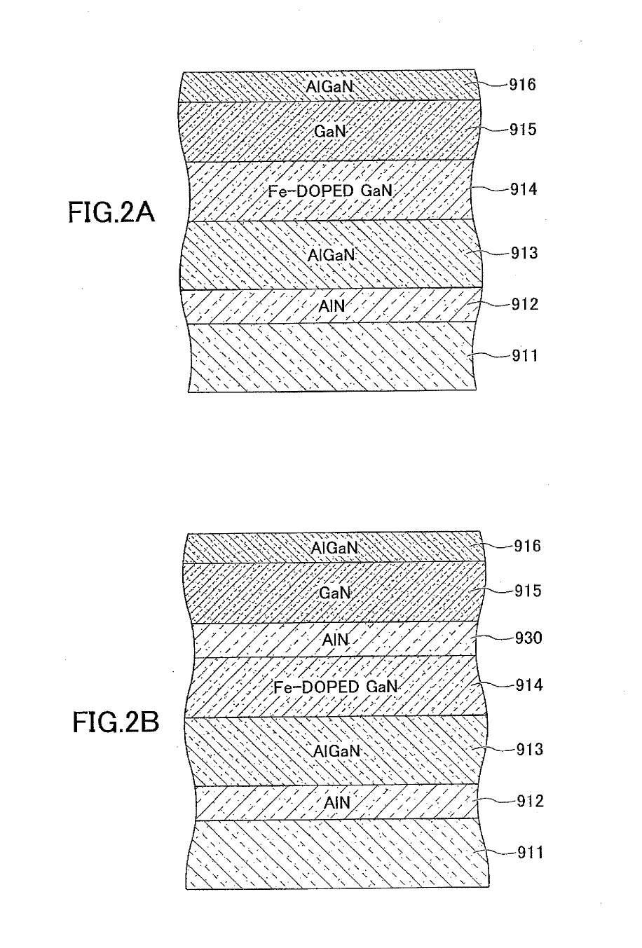

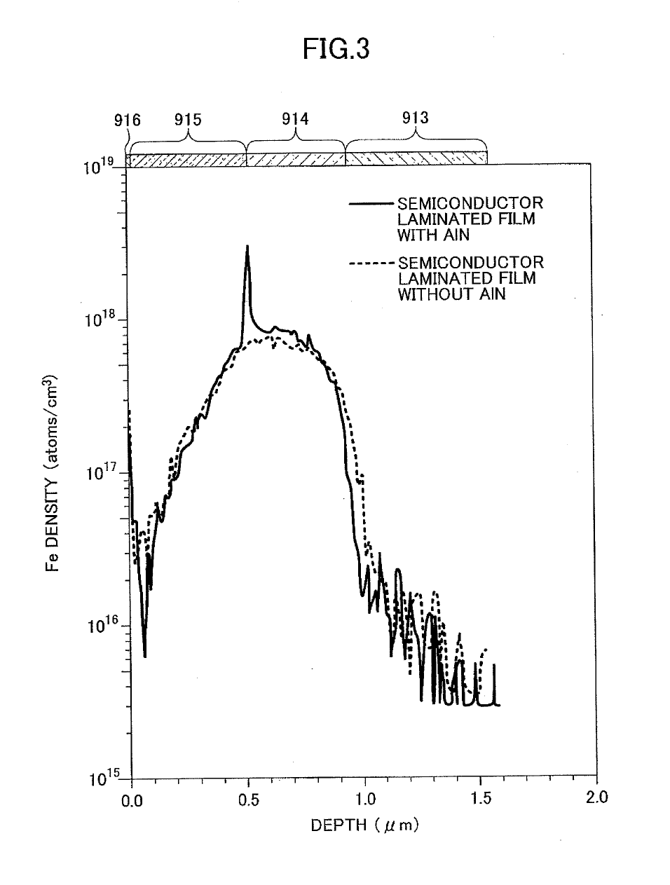

First, a description is given of the amount of Fe entering the electron transit layer, in a case where an AlN layer is provided and in a case where an AlN layer is not provided. As semiconductor laminated films for forming the HEMT illustrated in FIGS. 2A and 2B, a film provided with an AlN layer and a film not provided with an AlN layer were formed, and measurement was performed by SIMS (Secondary Ion-microprobe Mass Spectrometer). FIG. 3 illustrates a profile of Fe density in the depth direction in the semiconductor laminated films, measured by SIMS. FIG. 2A illustrates a structure of a semiconductor laminated film that is not provided with an AlN layer (semiconductor laminated film without AlN). On a substrate 911, a nucleation layer 912, a buffer layer 913, a high resistance layer 914, an electron transit layer 915, and an electron supply layer 916 are formed. FIG. 2B illustrates a structure of a semiconductor laminated film that is provided with an AlN layer (semiconductor laminated film with AlN). On a substrate 911, a nucleation layer 912, a buffer layer 913, a high resistance layer 914, an intermediate layer 930, an electron transit layer 915, and an electron supply layer 916 are formed. The high resistance layer 914 is formed with GaN doped with Fe as an impurity element. The high resistance layer 914 has a thickness of approximately 300 nm, and the density of the doped Fe is approximately 1×10¹⁸ cm⁻³. Furthermore, the electron transit layer 915 is formed with GaN having a thickness of approximately 600 nm, and the electron supply layer 916 is formed with AlGaN having a thickness of approximately 20 nm. Furthermore, in the case of the semiconductor laminated film with AlN illustrated in FIG. 2B, the intermediate layer 930 is formed with AlN having a thickness of approximately 5 nm. FIG. 3 indicates measurement results obtained by SIMS in the depth direction between the electron supply layer 916 and the buffer layer 913. Although not indicated in FIG. 3, in the semiconductor laminated film with AlN, the intermediate layer 930 is formed between the high resistance layer 914 and the electron transit layer 915.

In the case of the semiconductor laminated film without AlN, Fe has entered into the portion near the interface between the electron supply layer 916 and the electron transit layer 915, and the density of Fe sit this portion is greater than 2×10¹⁶ cm⁻³. Meanwhile, in the case of the semiconductor laminated film with AlN, the density of Fe peaks at the area where the intermediate layer 930 formed with AlN is formed between the high resistance layer 914 and the electron transit layer 915, and a large amount of Fe is taken in the intermediate layer 930. Therefore, the amount, of Fe entering the electron transit layer 915 is less than that of the semiconductor laminated film without AlN. As described above, by providing the intermediate layer 930 formed with AlN, it is possible to reduce the amount of Fe entering the electron transit layer 915.

### Semiconductor Device

Next, a description is given of a semiconductor device according to a first embodiment. The semiconductor device according to the present embodiment is a HEMT having an AlGaN/GaN single hetero structure.

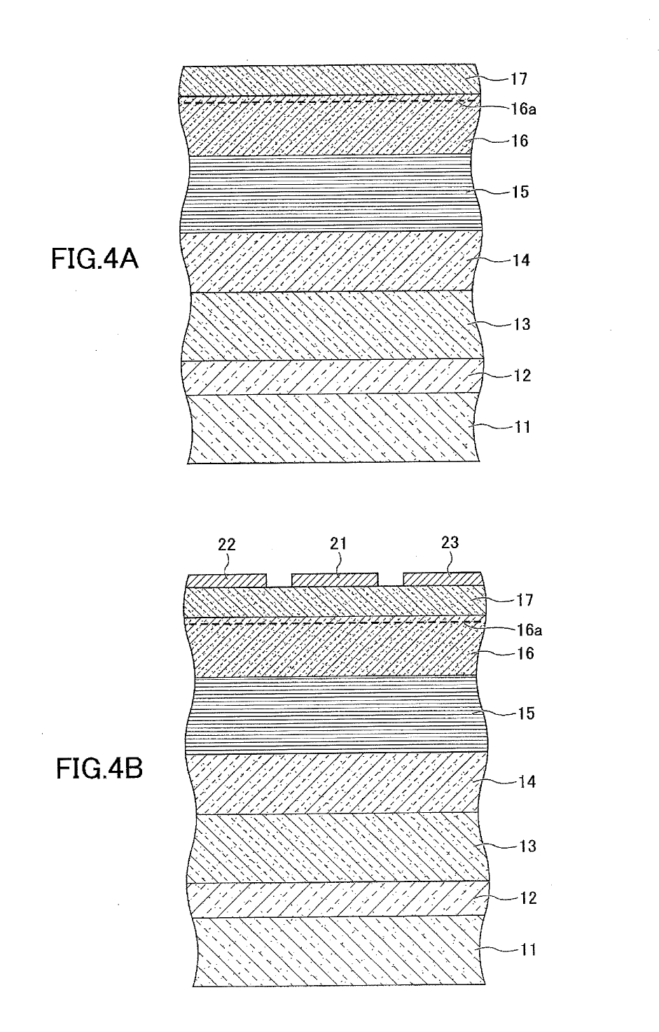

The semiconductor device according to the present embodiment is formed as follows. First, as illustrated in FIG. 4A, a nucleation layer 12 that is a nitride semiconductor layer, a buffer layer 13, a high resistance layer 14, a multilayer intermediate layer 15, art electron transit layer 16, and an electron supply layer 17, are sequentially laminated on a substrate 11. Specifically, first, a heating process is performed on the substrate 11 for several minutes in a hydrogen atmosphere. Subsequently, the nucleation layer 12, the buffer layer 13, the high resistance layer 14, the multilayer intermediate layer 15, the electron transit layer 16, and the electron supply layer 17 are epitaxially grown on the substrate 11 by a MOVPE (Metal Organic Vapor Phase Epitaxy) method. Accordingly, in the electron supply layer 16, near the interface between the electron transit layer 16 and the electron supply layer 17, 2DEG 16a is formed. At this time, TMG (trimethyl gallium) is used as the raw material gas of Ga, TMA (trimethyl aluminium) is used as the raw material gas of Al, and NH₃ (ammonia) is used as the raw material gas of N. Furthermore, Cp₂Fe (cyclopentadienyl iron, usually ferrocene) is used as the raw material gas of Fe used for doping as an impurity element. The raw material gas described above is supplied to a reacting furnace of a MOVPE device by using hydrogen (H₂) as carrier gas.

The substrate 11 is formed with a material such as sapphire. Si and SiC. In the present embodiment, for example, the substrate 11 is formed with Si. The substrate 11 is preferably formed with a material with high resistance to prevent current from leaking to the substrate 11.

The nucleation layer 12 is formed with an AlN layer having a thickness of 100 nm through 200 nm.

The buffer layer 13 is formed by AlGaN layers. In the present embodiment, AlGaN layers having different Al composition ratios are laminated to form the buffer layer 13. Specifically, first, a layer is formed with Al_{0.7}Ga_{0.3}N having a relatively high Al composition ratio. Subsequently, a layer is formed with Al_{0.3}Ga_{0.3}N having a relatively low Al composition ratio. The buffer layer 13 may be formed by three or more layers of AlGaN having different composition ratios. Furthermore, other than the above structures, the buffer layer 13 may be formed with a superlattice buffer having a periodic structure in which GaN and AlN are alternately formed, or a composition tilted structure in which the composition ratio of Al is changed from AlN to GaN. In order to reduce the rearrangement caused by the substrate 11, the buffer layer 13 is preferably thick. However, for the purpose of preventing cracks from being formed, the buffer layer 13 is preferably thin. Therefore, the preferable thickness of the buffer layer 13 is 200 nm through 1000 nm.

The high resistance layer 14 has a thickness of 100 nm through 300 nm, and is formed with GaN, AlN, or AlGaN doped with Fe as an impurity element that becomes high resistance. The doping density of Fe in the high resistance layer 14 is 5×10¹⁷ cm⁻³ through 1×10¹⁹ cm⁻³, more preferably 1×10¹⁸ cm⁻³. In the present application, the impurity element that becomes high resistance means that by doping a nitride semiconductor such as GaN, AlN, or AlGaN with the impurity element, the resistance of the nitride semiconductor is made high.

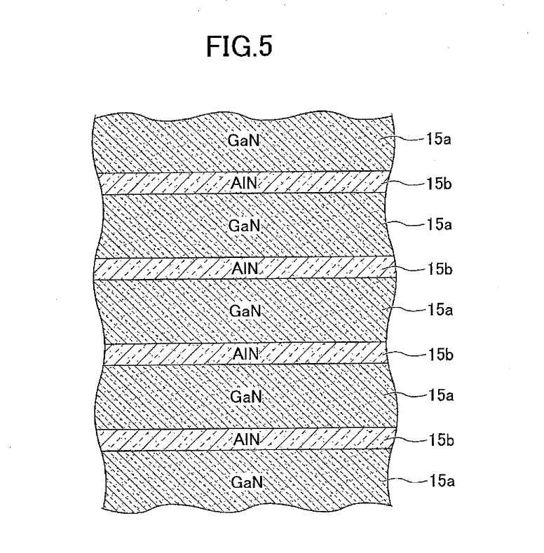

As illustrated in FIG. 5, the multilayer intermediate layer 15 is formed by alternately laminating a GaN layer 15a and an AlN layer 15b, and the thickness of the multilayer intermediate layer 15 is 500 nm through 1000 nm. In the multilayer intermediate layer 15, to prevent the overall stress balance including the substrate 11 from decreasing, the thickness of the GaN layer 15a is preferably greater than that of the AlN layer 15b.

Specifically, the thickness of the GaN layer 15a is preferably 20 nm through 50 nm, and the thickness of the AlN layer 15b is preferably 2 nm through 5 nm. In the present embodiment, the multilayer intermediate layer 15 is formed by growing 20 or more periods of alternately laminated GaN layers 15a having a thickness of approximately 20 nm and AlN layers 15b having a thickness of approximately 2 nm. In order to effectively prevent Fe from entering the electron transit layer 16, the thickness of the laminated AlN layer 15b is preferably greater than a certain value. Based on past experiences, the thickness of the laminated AlN layer 15b is preferably 40 nm or more.

The electron transit layer 16 is formed with GaN. To prevent the electron concentration and the mobility from decreasing due to rearrangement, the thickness of the electron transit layer 16 is preferably greater than a certain value, i.e., preferably 500 nm through 1000 nm.

The electron supply layer 17 is formed with AlGaN having a thickness of approximately 20 nm. In order to prevent the crystallinity from decreasing due to lattice mismatch, the electron supply layer 17 is formed such that the value of X is less than or equal to 0.3 when expressed as AlₓGa₁₋ₓN.

Next, as illustrated in FIG. 4B, on the electron supply layer 17, a gate electrode 21, a source electrode 22, and a drain electrode 23 are formed. Accordingly, the semiconductor device according to the present embodiment is manufactured.

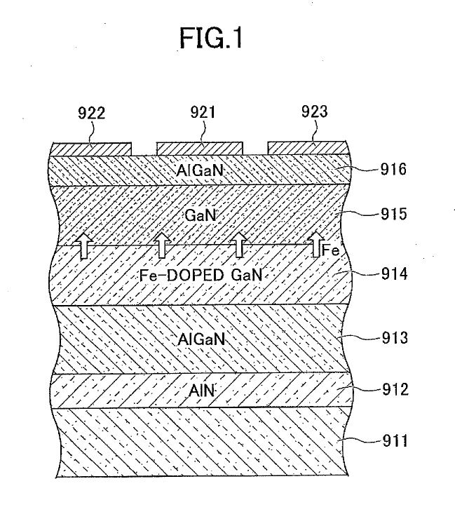

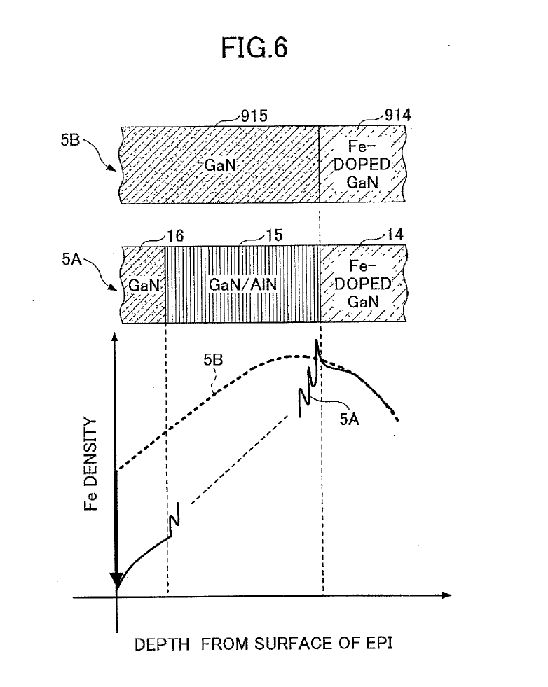

FIG. 6 illustrates the Fe density between the high resistance layer and the electron transit layer, in the HEMT that is a semiconductor device according to the present embodiment and the HEMT having the structure illustrated in FIG. 1. As illustrated in FIG. 6, in the HEMT 5A according to the present embodiment, a large amount of Fe is taken in the AlN layer 15b in the multilayer intermediate layer 15. Accordingly, the density of Fe entering the electron transit layer 16 in the HEMT 5A is lower than the density of Fe entering the electron transit layer 915 in a HEMT 5B having the structure illustrated in FIG. 1. Accordingly, in the HEMT that is the semiconductor device according to the present embodiment, electric properties are prevented from deteriorating, without increasing the resistance of the electron transit layer 16.

Furthermore, in the present embodiment, the multilayer intermediate layer 15 having a multilayer structure is formed by alternately laminating the GaN layer 15a and the AlN layer 15b. Therefore, the degree of stress is low, the substrate 11 is prevented from bending, and cracks are prevented from being formed in the semiconductor layer.

Accordingly, with the semiconductor device according to the present embodiment, it is possible to attain high yield and good electric properties.

### Second Embodiment

Next, a description is given of a semiconductor device according to a second embodiment. The semiconductor device according to the present embodiment is a HEMT of an AlGaN/GaN single hetero structure.

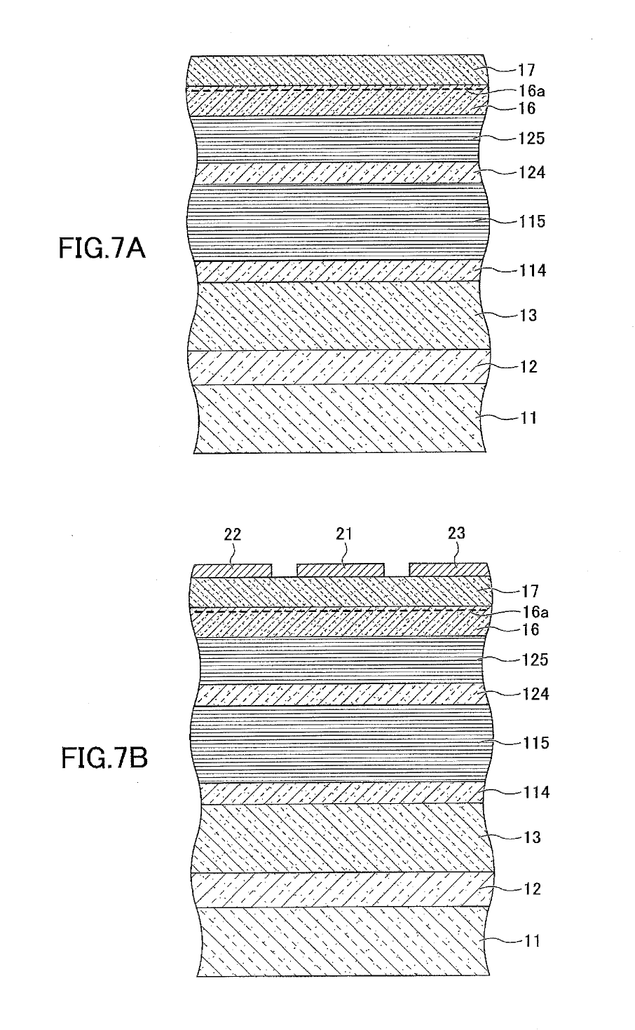

The semiconductor device according to the present embodiment is formed as follows. First, as illustrated in FIG. 7A, a nitride semiconductor layer is formed on the substrate 11. That is to say, a nucleation layer 12, a buffer layer 13, a first high resistance layer 114, a first multilayer intermediate layer 115, a second high resistance layer 124, a second multilayer intermediate layer 125, an electron transit layer 16, and an electron supply layer 17, are sequentially laminated on a substrate 11. Specifically, first, a heating process is performed on the substrate 11 for several minutes in a hydrogen atmosphere. Subsequently, the nucleation layer 12, the buffer layer 13, the first high resistance layer 114, the first multilayer intermediate layer 115, the second high resistance layer 124, the second multilayer intermediate layer 125, the electron transit layer 16, and the electron supply layer 17 are epitaxially grown on the substrate 11 by a MOVPE method. Accordingly, in the electron supply layer 16, near the interface between the electron transit layer 16 and the electron supply layer 17, 2DEG 16a is formed. At this time, TMG is used as the raw material gas of Ga, TMA is used as the raw material gas of Al, and NH₃ is used as the raw material gas of N. Furthermore, Cp₂ Fe is used as the raw material gas of Fe used for doping as an impurity element. The raw material gas described above is supplied to a reacting furnace of a MOVPE device by using hydrogen as carrier gas.

The first high resistance layer 114 has a thickness of 100 nm through 300 nm, and is formed with GaN, AlN, or AlGaN doped with Fe as an impurity element that becomes high resistance. The doping density of Fe in the first high resistance layer 114 is 5×10¹⁷ cm⁻³ through 1×10¹⁹ cm⁻³, more preferably 1×10¹⁸ cm⁻³.

As illustrated in FIG. 5, the first multilayer intermediate layer 115 is formed by alternately laminating a GaN layer 15a and an AlN layer 15b, and the thickness of the multilayer intermediate layer 15 is 500 nm through 1000 nm. In the first multilayer intermediate layer 115, to prevent the overall stress balance including the substrate 11 from decreasing, the thickness of the GaN layer 15a is preferably greater than that of the AlN layer 15b. Specifically, the thickness of the GaN layer 15a is preferably 20 nm through 50 nm, and the thickness of the AlN layer 15b is preferably 2 nm through 5 nm. In the present embodiment, the first multilayer intermediate layer 115 is formed by growing 20 or more periods of alternately laminated GaN layers 15a having a thickness of approximately 20 nm and the AlN layers 15b having a thickness of approximately 2 nm. In order to effectively prevent Fe from entering the electron transit layer 16, the thickness of the laminated AlN layer 15b is preferably greater than a certain value. Based on past experiences, the thickness of the laminated AlN layer 15b is preferably 40 nm or more.

The second high resistance layer 124 has a thickness of 50 nm through 10 nm, and is formed with GaN, AlN, or AlGaN doped with Fe as an impurity element that becomes high resistance. The doping density of Fe in the second high resistance layer 124 is 1×10¹⁷ cm⁻¹ through 1×10¹⁸ cm⁻³. In the second high resistance layer 124, the doping density of Fe is lower than that of the first high resistance layer 114, in order to prevent adverse effects on the transit electrons caused by an excessive amount of Fe being taken in the electron transit layer 16. Specifically, for example, the electron transit layer 16 is formed so that the doping density of Fe is 5×10¹⁷ cm⁻³. Furthermore, the thickness of the second high resistance layer 124 is preferably less than that of the first high resistance layer 114.

As illustrated in FIG. 5, the second multilayer intermediate layer 125 is formed by alternately laminating a GaN layer 15a and an AlN layer 15b, and the thickness of the second multilayer intermediate layer 125 is 125 nm through 500 nm. In the second multilayer intermediate layer 125, the thickness of the GaN layer 15a is preferably greater than that of the AlN layer 15b. Specifically, the thickness of the GaN layer 15a is preferably 20 nm through 50 nm, and the thickness of the AlN layer 15b is preferably 2 nm through 5 nm. In the present embodiment, the second multilayer intermediate layer 125 is formed by growing 5 through 10 periods of alternately laminated GaN layers 15a having a thickness of approximately 30 nm and the AlN layers 15b having a thickness of approximately 2 nm. In the present embodiment, the density of Fe in the second high resistance layer 124 is lower than that in the first high resistance layer 114, and therefore, the ratio of the thickness of the AlN layer 15b in the second multilayer intermediate layer 125 is lower than the ratio of the thickness of the AlN layer 15b in the first multilayer intermediate layer 115. That is to say, the thickness ratio of (the thickness of the GaN layer)/(the thickness of the AlN layer) in the second multilayer intermediate layer 125 is greater than the thickness ratio of (the thickness of the GaN layer)/(the thickness of the AlN layer) in the first multilayer intermediate layer 115.

The electron transit layer 16 is formed with GaN. To prevent the electron concentration and the mobility from decreasing due to rearrangement, the thickness of the electron transit layer 16 is preferably greater than a certain value, i.e., preferably 500 nm through 1000 nm. In the present embodiment, by forming the first multilayer intermediate layer 115 and the second multilayer intermediate layer 125, rearrangement is significantly prevented, and therefore the thickness of the electron transit layer 16 is less than that in the semiconductor device according to the first embodiment. Accordingly, in the semiconductor device according to the present embodiment, the thickness of the electron transit layer 16 is reduced while maintaining the crystallinity of the electron transit layer 16, and therefore pinch-off properties are improved.

Next, as illustrated in FIG. 7B, on the electron supply layer 17, the gate electrode 21, the source electrode 22, and the drain electrode 23 are formed. Accordingly, the semiconductor device according to the present embodiment is manufactured.

In the present embodiment, by providing the first high resistance layer 114 and the second high resistance layer 124, it is possible to prevent vertical leaks and to reduce the thickness of the electron transit layer 16, and therefore pinch-off properties are improved.

Contents other than the above are the same as the first embodiment.

### Third Embodiment

Next, a description is given of a third embodiment. The semiconductor device according to the present embodiment includes a mixed crystal intermediate layer formed with a mixed crystal of AlN and GaN, instead of the multilayer intermediate layer 15 according to the first embodiment.

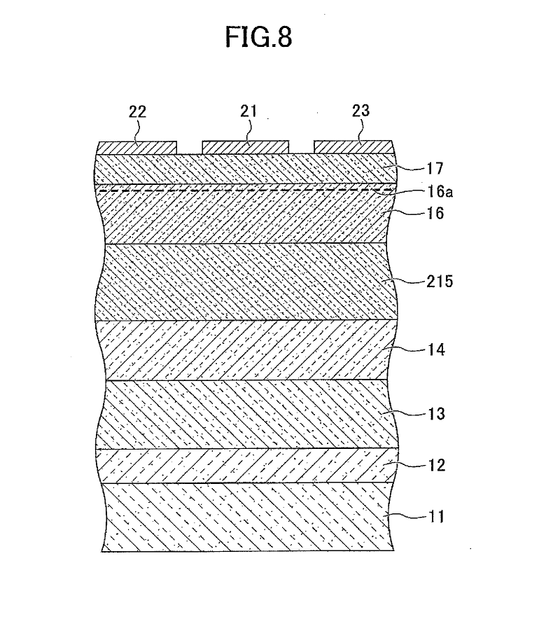

With reference to FIG. 8, a description is given of a semiconductor device according to the present embodiment. The semiconductor device according to the present embodiment is formed as follows. A nucleation layer 12, a buffer layer 13, a high resistance layer 14, a mixed crystal intermediate layer 215, an electron transit, layer 16, and an electron supply layer 17, are sequentially laminated on a substrate 11.

The mixed crystal intermediate layer 215 is formed with a mixed crystal of AlN and GaN having a thickness of 500 nm through 1000 nm. Assuming that the composition of the mixed crystal intermediate layer 215 is AlₓGa₁₋ₓN, the mixed crystal intermediate layer 215 is formed such that 0<X<0.3, more preferably, 0.04≦X≦0.25 is satisfied. If the mixed crystal intermediate layer 215 includes even a slight amount of Al, it is possible to take in Fe, and Fe is prevented from entering the electron transit layer 16. Furthermore, if X<0.3 is satisfied, the occurrence of stress is reduced, and therefore the substrate 11 is prevented from bending and cracks are prevented from being formed in the laminated semiconductor layer.

Contents other than the above are the same as the first embodiment.

### Fourth Embodiment

Next, a description is given of a fourth

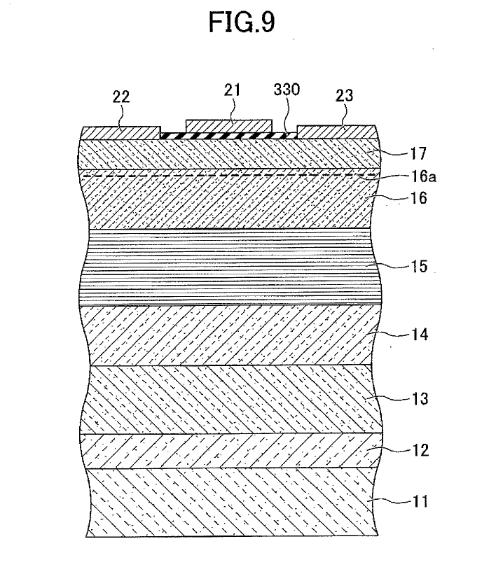

embodiment with reference to FIG. 9. In the semiconductor device according; to the present embodiment, an insulating film 330 that is a gate insulating film is formed on the electron supply layer 17. By forming the insulating film 330, it is possible to reduce the gate leakage current. For example, Al₂O₃ (aluminum oxide) is used as the insulating film 330.

The semiconductor device according to the present embodiment is formed by forming the source electrode 22 and the drain electrode 23 on the electron supply layer 17 of the semiconductor device formed up to the state illustrated in FIG. 4A according to the first embodiment, and the insulating film 330 acting as a gate insulating film is formed. The methods of forming the insulating film 330 include CVD (Chemical Vapor Deposition), ALD (Atomic Layer Deposition), and sputtering.

Then, in a predetermined area on the insulating film 330, the gate electrode 21 is formed. Accordingly, the semiconductor device according to the present embodiment is manufactured. Furthermore, a gate recess having a recessed shape may be formed in the area where the gate electrode 21 is to be formed, and the gate electrode 21 may be formed in an area including the inside of the gate recess.

Contents other than the above are the same as the first embodiment. Furthermore, the present embodiment is also applicable to the semiconductor device according to the second and third embodiments.

### Fifth Embodiment

Next, a description is given of a fifth embodiment. The present embodiment is pertinent to a semiconductor device, a power unit, and a high-frequency amplifier.

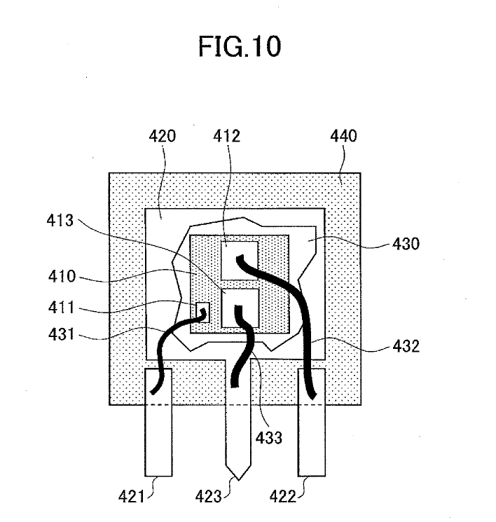

The semiconductor device according to the present embodiment is formed by discretely packaging the semiconductor device. The discretely packaged semiconductor device is described with reference to FIG. 10. FIG. 10 schematically illustrates the inside of the discretely packaged semiconductor device, in which the arrangements of the electrodes are different from those of the first through fourth embodiments.

First, the semiconductor device manufactured according to the first through fourth embodiments is cut by dicing, and a semiconductor chip 410 that Is a HEMT made of a GaN system material is formed. The semiconductor chip 410 is fixed on a lead frame 420 by a diatouch agent 430 such as solder. The semiconductor chip 410 corresponds to the semiconductor device according to the first through fourth embodiments.

Next, the gate electrode 411 is connected to a gate lead 421 by a bonding wire 431, the source electrode 412 is connected to a source lead 422 by a bonding wire 432, and the drain electrode 413 is connected to a drain lead 423 by a bonding wire 433. The bonding wires 431, 432, and 433 are formed by a metal material such as Al. Furthermore, in the present embodiment, the gate electrode 411 is a gate electrode pad, which is connected to the gate electrode 21 of the semiconductor device according to the first to fourth embodiments. Furthermore, the source electrode 412 is a source electrode pad, which is connected to the source electrode 22 of the semiconductor device according to the first to fourth embodiments. Furthermore, the drain electrode 413 is a drain electrode pad, which, is connected to the drain electrode 23 of the semiconductor device according to the first to fourth embodiments.

Next, resin sealing is performed with mold resin 440 by a transfer mold method. As described above, a discretely packaged semiconductor chip that, is a HEMT made of a GaN system, material is manufactured.

Next, a description is given of the power unit and the high-frequency amplifier according to the present embodiment. The power unit and the high-frequency amplifier according to the present embodiment use any one of the semiconductor devices according to the first through fourth embodiments.

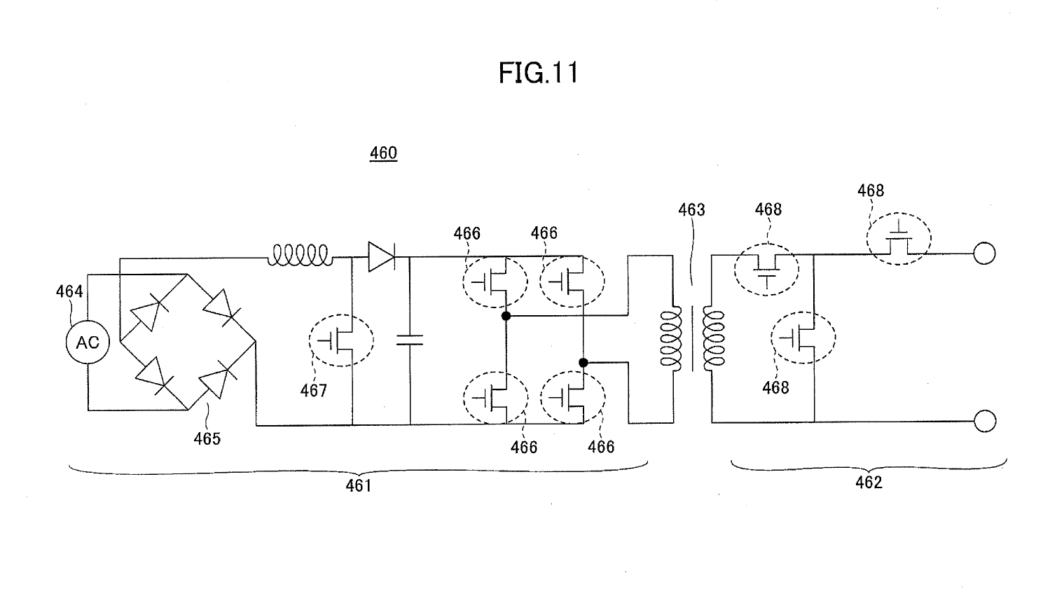

First, with reference to FIG. 11, a description is given of the power unit according to the present embodiment. A power unit 460 according to the present embodiment includes a high voltage primary side circuit 461, a low voltage secondary side circuit 462, and a transformer 463 disposed between the high voltage primary side circuit 461 and the low voltage secondary side circuit 462. The high voltage primary side circuit 461 includes an AC (alternating-current) source 464, a so-called bridge rectifier circuit 465, plural switching elements (four in the example of FIG. 11) 466, and one switching element 467. The low voltage secondary side circuit 462 includes plural switching elements 468 (three in the example of FIG. 11). In the example of FIG. 11, the semiconductor device according to the first through fourth embodiments is used as the switching elements 466 and the switching element 467 of the high voltage primary side circuit 461. The switching elements 466 and 467 of the primary side circuit 461 are preferably normally-off semiconductor devices. Furthermore, switching elements 468 used in the low voltage secondary side circuit 462 are typical MISFET (metal insulator semiconductor field effect transistor) made of silicon.

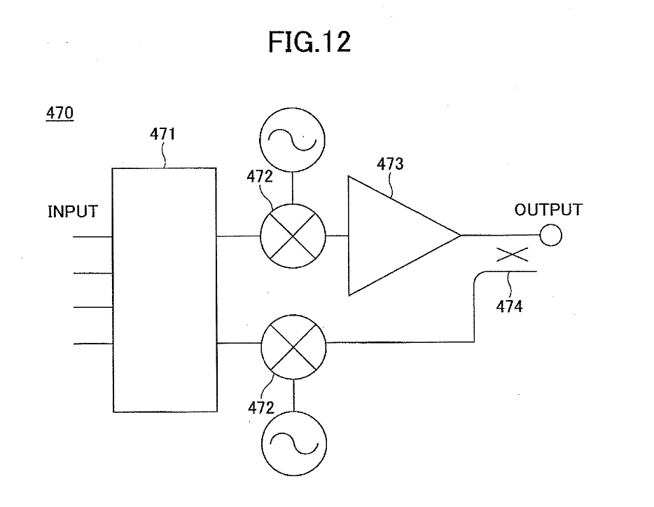

Next, with reference to FIG. 12, a description is given of the high-frequency amplifier according to the present embodiment. A high-frequency amplifier 470 according to the present embodiment may be applied to a power amplifier of a base station of mobile phones. The high-frequency amplifier 470 includes a digital predistortion circuit 471, mixers 472, a power amplifier 473, and a directional coupler 474. The digital predistortion circuit 471 offsets the non-linear strains of input, signals. The mixers 472 mix the input signals, whose non-linear strains have been offset, with AC signals. The power amplifier 473 amplifies the input signals that have been mixed with the AC signals. In the example of FIG. 12, the power amplifier 473 includes the semiconductor device according to the first through fourth embodiments. The directional coupler 474 monitors input signals and output signals. In the circuit of FIG. 12, for example, the switch may be switched so that output signals are mixed with AC signals by the mixers 472 and sent to the digital predistortion circuit 471.

According to an aspect of the embodiments, in a semiconductor device such as a field-effect transistor, Fe is prevented from entering the electron transit layer, and cracks are prevented from being formed in the semiconductor layer, and therefore it is possible to attain high yield and good electric properties.

The semiconductor device is not limited to the specific embodiments described herein, and variations and modifications may be made without departing from the scope of the present invention.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described, in detail, it should be understood that the various changes, substitutions, and alterations could be made hereto without departing from the spirit and scope of the invention.

What is claimed is:

1. A semiconductor device comprising: a high resistance layer formed on a substrate, the high resistance layer being formed with a semiconductor material doped with an impurity element that makes the semiconductor material highly resistant; a multilayer intermediate layer formed on the high resistance layer; an electron transit layer formed with a semiconductor material on the multilayer intermediate layer; and an electron supply layer formed with a semiconductor material on the electron transit layer, wherein the multilayer intermediate layer is formed with a multilayer film in which a GaN layer and an AlN layer are alternately laminated, the high resistance layer is a first high resistance layer, and the multilayer intermediate layer is a first multilayer intermediate layer, the semiconductor device further comprising a second high resistance layer formed on the first high resistance layer, the second high resistance layer being formed with a semiconductor material doped with an impurity element that makes the semiconductor material highly resistant, and a second multilayer intermediate layer formed on the second high resistance layer, wherein the electron transit layer is formed on the second multilayer intermediate layer, and the second multilayer intermediate layer is formed with a multilayer film in which a GaN layer and an AlN layer are alternately laminated.

2. The semiconductor device according to claim 1, wherein a doping density of the impurity element in the second high resistance layer is lower than a doping density at the impurity element in the first high resistance layer.

3. The semiconductor device according to claim 2, wherein a thickness of the second high resistance layer is less than a thickness of the first high resistance layer

4. The semiconductor device according to claim 1, wherein a thickness of the second multilayer intermediate layer is less than a thickness of the first multilayer intermediate layer.

5. The semiconductor device according to claim 1, therein a thickness ratio of (thickness of GaN layer)/(thickness of AlN layer) in the second multilayer intermediate layer in greater than a thickness ratio of (thickness of GaN layer)/(thickness of AlN multilayer) in the first multilayer intermediate layer.

6. A semiconductor device comprising: a high resistance layer formed on a substrate, the high resistance layer being formed with a semiconductor material doped with an impurity element chat makes the semi conductor material highly resistant; a multilayer intermediate layer formed on the high resistance layer; an electron transit layer formed with a semiconductor material on the multilayer intermediate layer; and an electron supply layer formed with a semiconductor material on the electron transit layer, wherein the multilayer intermediate layer is formed with a multilayer film in which a GaN layer and an AlN layer are alternately laminated

7. The semiconductor device according to claim 6, wherein a gate electrode, a source, electrode, and a drain electrode are formed on the electron supply layer.

8. A power unit comprising: the semiconductor device according to claim 6.

9. An amplifier comprising: the semiconductor device according to claim 6.
